(19) United States
(12) Patent Application Publication
(10) Pub. No.: US 2025/0198851 A1
(43) Pub. Date: Jun. 19, 2025

(54) Active Mitigation of Degradation in Battery Packs

(71) Applicant: ZEBRA TECHNOLOGIES CORPORATION, Lincolnshire, IL (US)

(72) Inventors: Michael Robustelli, Smithtown, NY (US); Rohan Chopra, Syosset, NY (US); Gaurav Gothoskar, St. James, NY (US)

(21) Appl. No.: 18/542,150

(22) Filed: Dec. 15, 2023

(51) Int. Cl. G01K 3/00; G01R 31/382; H02J 7/00

(52) U.S. Cl. CPC G01K 3/005; G01R 31/382; H02J 7/007194

(57) ABSTRACT

A method includes: monitoring an ambient temperature associated with a battery pack; in response to detecting that the ambient temperature exceeds a temperature threshold, initializing an excursion timer; determining whether the excursion timer exceeds a time threshold; and when the excursion timer exceeds the time threshold, executing a mitigation action at the battery pack.

### BACKGROUND

Battery packs, e.g., rechargeable batteries for computing devices, can be employed in a wide variety of operating environments. Storing battery packs under certain environmental conditions, such as at elevated temperatures, can lead to accelerated degradation of the battery packs, e.g., leading to premature reductions in capacity and/or to failure.

### BRIEF DESCRIPTION OF THE SEVERAL VIEWS OF THE DRAWINGS

The accompanying figures, where like reference numerals refer to identical or functionally similar elements throughout the separate views, together with the detailed description below, are incorporated in and form part of the specification, and serve to further illustrate embodiments of concepts that include the claimed invention, and explain various principles and advantages of those embodiments.

FIG. 1 is a diagram of a computing device with a battery pack.

FIG. 2 is a diagram of certain internal components of the battery pack and the computing device of FIG. 1.

FIG. 3 is a diagram illustrating an example performance of blocks 205, 210, 220 and 225 of the method of FIG. 2.

FIG. 4 is a diagram illustrating selection of a time threshold at block 320 of the method of FIG. 3.

FIG. 5 is a diagram illustrating example mitigation actions for use at block 325 of the method of FIG. 3.

FIG. 6 is a diagram illustrating an example performance of block 325 of the method of FIG. 2.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

The apparatus and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

### DETAILED DESCRIPTION

Examples disclosed herein are directed to a method, comprising: monitoring an ambient temperature associated with a battery pack; in response to detecting that the ambient temperature exceeds a temperature threshold, initializing an excursion timer; determining whether the excursion timer exceeds a time threshold; and when the excursion timer exceeds the time threshold, executing a mitigation action at the battery pack.

Additional examples disclosed herein are directed to a battery pack, comprising: a temperature sensor; and a controller configured to: monitor an ambient temperature associated with a battery pack; in response to detecting that the ambient temperature exceeds a temperature threshold, initialize an excursion timer; determine whether the excursion timer exceeds a time threshold; and when the excursion timer exceeds the time threshold, execute a mitigation action at the battery pack.

Further examples disclosed herein are directed to a device, comprising: a controller configured to: monitor an ambient temperature associated with a battery pack; in response to detecting that the ambient temperature exceeds a temperature threshold, initialize an excursion timer; determine whether the excursion timer exceeds a time threshold; and when the excursion timer exceeds the time threshold, initiate a mitigation action at the battery pack.

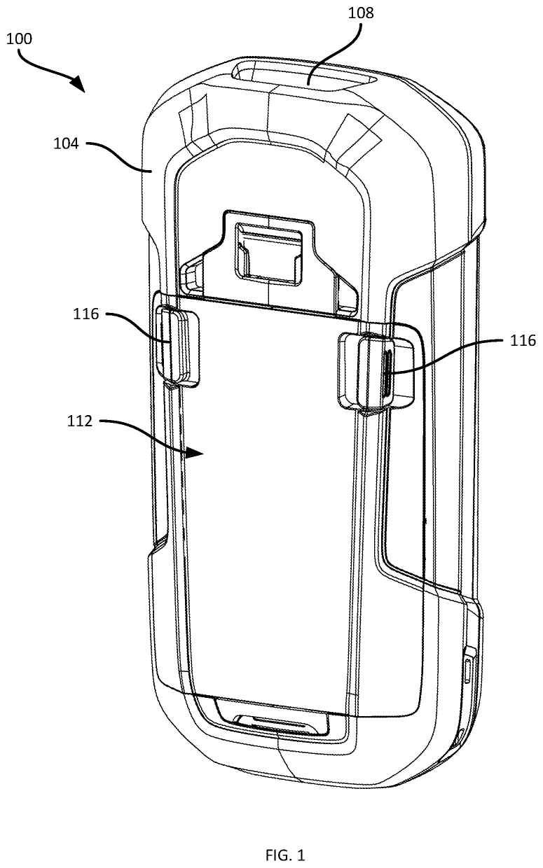

FIG. 1 depicts an example computing device 100, such as a mobile computing device. The device 100 is implemented as a handheld computer in the example shown in FIG. 1, although the device 100 can be implemented in any of a variety of other form factors, including laptop computers, tablet computers, smartphones, mobile printers, barcode scanners, and the like. The device 100 includes a housing 104 supporting various other components of the device 100, such as a display (facing into the page, and therefore not visible in FIG. 1), keypad, touch screen, barcode scanning assembly 108, and the like. The selection of components supported by the housing 104 can vary widely with the nature of the device 100.

The device 100 can be powered by a battery pack 112, e.g., releasably secured to the housing 104. For example, the battery pack 112, also referred to herein simply as the battery 112, can include movable latches 116 configured to engage with or disengage from complementary features of the housing 104, to engage and release the battery pack 112 from the housing 104. The housing 104 can include, e.g., within a battery compartment defined by the housing 104, electrical contacts to receive power from the battery pack 112 and, in some cases, exchange data with the battery pack 112 (e.g., state of charge or SoC data, and the like).

As will be understood by those skilled in the art, discharging and charging the battery pack 112, e.g., via use to power the device 100, may degrade the capacity of the battery pack 112 over time. Other factors beyond use to power the device 100 may also affect the capacity of the battery pack 112, however. For example, exposure of the battery 112 to elevated temperatures, particularly for prolonged periods (e.g., days or weeks), may permanently degrade the cells of the battery 112, potentially reducing the useful lifespan of the battery 112. Further, lengthy idle periods (e.g., periods of days or weeks in which the battery 112 is not used to power the device 100) at a high state of charge (e.g., above about 95%, although the particular threshold may vary depending on battery type) may also lead to accelerated cell degradation. It follows from the above that storage of the battery 112 at both a high state of charge and a high temperature can negatively affect performance and/or lifespan of the battery 112.

Storage at one or both of high temperatures and high states of charge may occur in a variety of operating conditions. For example, spare battery packs may be stored (generally at full charge) in a vehicle or other space with little or no environmental controls and therefore prone to heating significantly based on weather or the like. The battery pack 112 is therefore configured to implement certain functions, described below, to detect conditions that may be detrimental to battery performance and/or lifespan, and to select and execute various actions to mitigate the impact of such conditions.

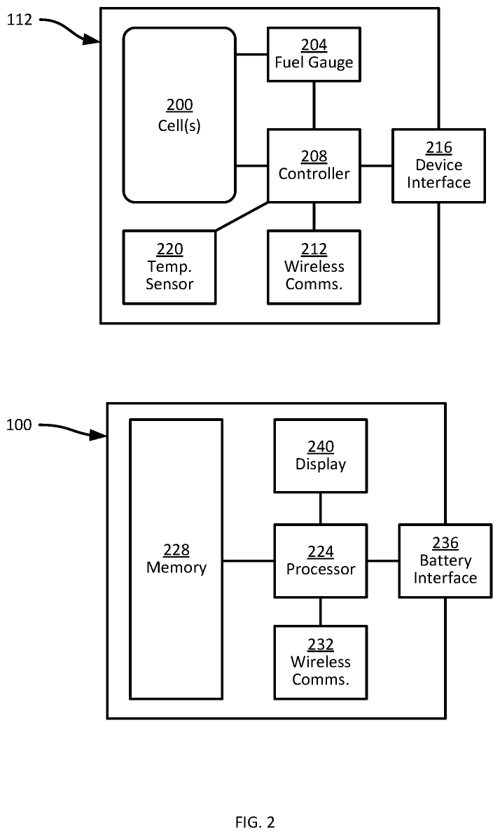

FIG. 2 illustrates certain internal components of the battery pack 112 and of the device 100. The battery pack 112 includes one or more energy storage cells 200 of any suitable cell structure, chemistry, and the like. The battery 112 can also include a fuel gauge 204, such as an integrated circuit (IC) configured to periodically measure one or more attributes of the cells 200 and generate an SoC indicator, e.g., expressed as a percentage (with 100% indicating full charge). The fuel gauge 204 can also determine other metrics, such as a state of health (SoH) or the like.

The battery 112 also includes a controller 208, such as a suitable programmable microcontroller (e.g., a field-programmable gate array (FPGA) or the like). The controller 208 can be coupled with or integrated with a non-transitory computer readable medium such as one or more memory circuits for storing data and/or instructions executable by the controller 208 to control certain aspects of the operation of the battery 112. For example, the controller 208 can be integrated with an electrically-erasable programmable read-only memory (EEPROM) containing firmware instructions executable by the controller 208, and a flash memory device for data storage. In some examples, the fuel gauge 204 can be implemented by the controller 208, rather than as a separate physical component as shown in FIG. 2.

The battery 112 also includes a wireless communications interface 212, e.g. implementing a short-range communications protocol such as Bluetooth™ Low Energy (BLE) or the like. The battery 112 further includes a device interface 216, such as a set of electrical contacts configured to engage with corresponding contacts of the device 100 for power delivery and/or data exchange.

The battery 112 further includes a temperature sensor 220 connected with the controller 208. The temperature sensor 220 is configured to periodically report a temperature associated with the battery 112 to the controller 208 for further processing as discussed below. When the battery 112 is idle (e.g., not supplying power to an external load such as the device 100), the temperature reported by the sensor 220 is substantially equal to the ambient temperature of the external environment of the battery 112. As described below, via execution of the instructions stored at the controller 208 or other suitable memory device, the controller 208 is configured to monitor data from the sensor 208 and the fuel gauge and/or cells 200 to detect conditions that may cause accelerated cell degradation.

The device 100 includes a processor 224, such as a central processing unit (CPU), graphics processing unit (GPU), or the like, connected with a memory 228 (e.g., a suitable combination of volatile and non-volatile memory elements). The memory 228 can store computer-executable instructions, e.g., for execution by the processor 224 to perform various functionality. In some examples, the processor 224 can, via the execution of such instructions, perform functions related to the detection of conditions that may cause accelerated cell degradation at the battery 112, and to the mitigation of such conditions. The device 100 can also include a wireless communications interface 232, and a battery interface 236 configured to engage with the interface 216 of the battery 112. The device 100 can further include input and/or output devices, such as a display 240.

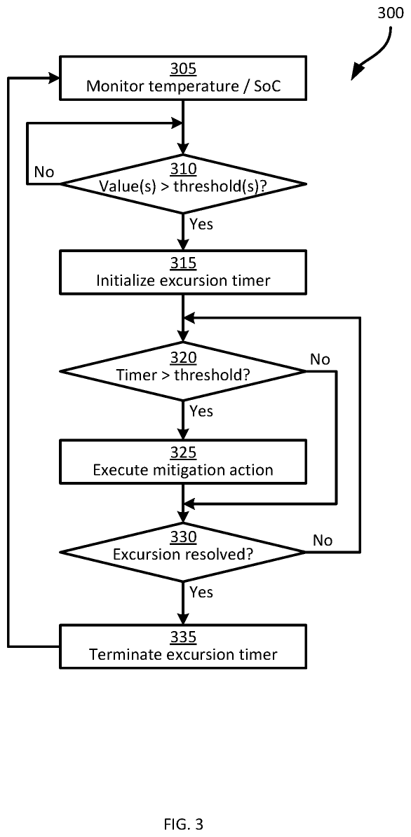

Turning to FIG. 3, a method 300 of actively mitigating battery pack degradation is illustrated. The method 300 is described below in conjunction with its performance in the battery pack 112, e.g., via execution of firmware instructions by the controller 208.

At block 305, the controller 208 is configured to initiate monitoring of one or both of ambient temperature, via the sensor 220, and state of charge, e.g., via communication with the fuel gauge 204, or by implementing the fuel gauge 204 locally. The controller 208 can, for example, obtain ambient temperature measurements and SoC measurements periodically, at a predetermined frequency. For example, the controller 208 can obtain such measurements once every ten minutes, although higher and lower measurement frequencies can be used in other examples, and the frequency of measurement need not be the same for ambient temperature as for SoC. In some examples, the controller 208 can be configured to begin monitoring at block 305 in response to determining that the battery 112 is idle, e.g., not supplying power to an external load such as the device 100. The measurements obtained via such monitoring can be stored in a local memory, e.g., up to a historical buffer size dependent on the capacity of the local memory.

At block 310, the controller 208 is configured to determine whether either or both of a current value for ambient temperature, and a current SoC value, exceed respective thresholds. For example, the controller 208 can maintain a temperature threshold and an SoC threshold. The thresholds can be configurable in some examples, or can be defined statically in the firmware instructions of the battery 112. The temperature threshold is set at an ambient temperature above which the battery 112 may experience accelerated cell degradation over time. A wide variety of temperature thresholds can therefore be employed for different batteries 112, depending on the type and structure of the battery 112. The SoC threshold is also set at an SOC above which the battery 112 may experience accelerated cell degradation over time. As with the temperature threshold, the SoC threshold may therefore vary for different battery models. The temperature and SoC thresholds can be set, for example, based on manufacturer testing of a given battery model. The thresholds can also be configurable in some examples, e.g., when the battery 112 is engaged with the device 100. For example, certain device operators may elect to set more or less aggressive temperature and/or SoC thresholds (e.g., to cause the battery 112 to take mitigating actions more or less aggressively in response to environmental conditions).

In some examples, the determination at block 310 is affirmative if a current ambient temperature exceeds the temperature threshold, if the current SoC exceeds the SoC threshold, or both. In other examples, the determination at block 310 may be affirmative if a minimum number of consecutive samples exceed the temperature threshold or the SoC threshold (or both).

When neither the current temperature nor the current SoC exceed the corresponding thresholds, the determination at block 310 is negative, and the controller 208 continues monitoring ambient temperature and SoC. When the ambient temperature exceeds the temperature threshold (e.g., 60 degrees Celsius, for the purpose of illustration), when the SoC exceeds the SoC threshold (e.g., 95%, for the purpose of illustration), or both, the determination at block 310 is affirmative. The controller 208 can further be configured to store excursion records, e.g., along with or instead of the historical data mentioned above. For example, in response to an affirmative determination at block 310, the controller 208 can track, in an excursion log, a record of a length of time that the temperature and/or SoC exceeded the above-mentioned thresholds.

Following an affirmative determination at block 310, at block 315 the controller 208 is configured to initialize an excursion timer. The controller 208 also continues monitoring the ambient temperature and SoC, as set out above. The excursion timer measures a length of time during which the ambient temperature is above the temperature threshold, or the SoC is above the SoC threshold, or both. In other words, when the ambient temperature and the SoC are both below their respective thresholds, the controller 208 need not maintain an excursion timer, because the conditions to which the battery 112 is subject are not likely to accelerate cell degradation. When the ambient temperature and/or SoC are above the corresponding threshold(s), the battery 112 may experience accelerated cell degradation. A brief excursion (e.g., one hour at 65 degrees C.) may have a sufficiently small impact on the battery 112 that mitigating action can be neglected. The excursion timer is used by the controller 208 to assess when potentially detrimental conditions have persisted for a sufficient length of time to begin efforts to mitigate the effect of such conditions.

At block 320, the controller 208 is configured to determine whether the excursion timer initialized at block 315 has reached or exceeded a time threshold. The time threshold can be predetermined and static, e.g., defined in the firmware instructions executed by the controller 208. For example, the time threshold can be defined as a number of hours, days, weeks, or the like. In other examples, the controller 208 can select one of a plurality of predefined time thresholds, according to which of the temperature threshold and the SoC threshold were exceeded at block 310. When the determination at block 315 is affirmative, the controller 208 is configured to execute one or more mitigating actions, e.g., to mitigate the risk of accelerated cell degradation resulting from elevated temperature and/or SoC. In some examples, the excursion timer can be omitted, or bypassed, e.g., by setting the timer value to zero, such that the determination at block 320 is affirmative substantially simultaneously with an affirmative determination at block 310.

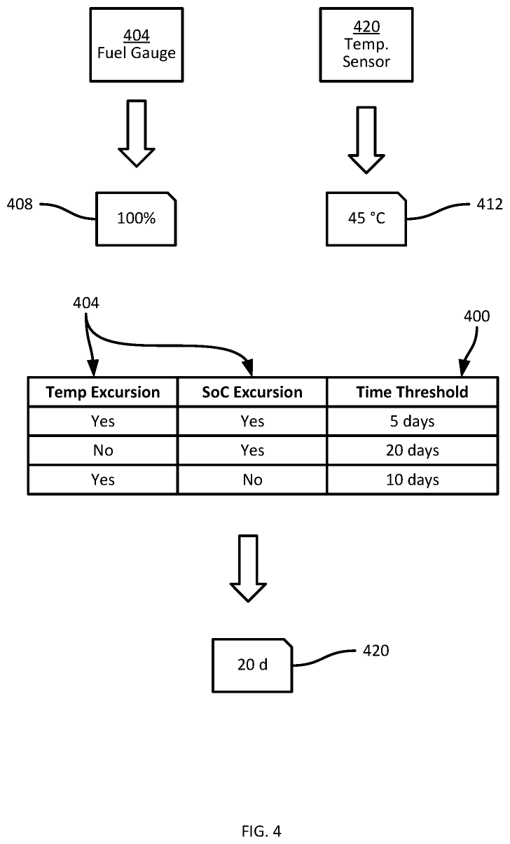

For example, as shown in FIG. 4, the controller 208 can maintain a set of time thresholds 400, e.g., associated with criteria 404 corresponding to the temperature and SoC thresholds. In the example shown in FIG. 4, a time threshold of five days is defined for elevated temperatures and SoC. A time threshold of twenty days is defined for elevated SoC but normal (e.g., sub-threshold) temperature, and a time threshold of ten days is defined for elevated temperature and normal SoC. In the example of FIG. 4, for a current SoC 408 of 100% and a current temperature 412 of 45 degrees C., the controller 208 is therefore configured to select an active time threshold 416 of twenty days, based on the criteria 404.

Various other mechanisms for selecting a time threshold at block 320 are contemplated. In some examples, the time threshold can be determined dynamically based on a difference between the current temperature and/or SoC and the corresponding thresholds. That is, the time threshold can be scaled shorter or longer based on a magnitude of temperature excursion and/or a magnitude of SoC excursion. For example, a time threshold can be selected from the thresholds 400, and decreased by a predetermined amount of time for each ten degrees of ambient temperature over the temperature threshold. A wide variety of other scaling mechanisms can also be used.

When the determination at block 320 is affirmative, indicating that one or more thresholds from block 310 have been exceeded for a predetermined length of time, the controller 208 is configured to proceed to block 325, to execute one or more mitigation actions. The mitigation action(s) executed at block 325 can be selected based, for example, on which thresholds are exceeded, and in some examples based on the magnitude of excursion for either or both of ambient temperature and SoC.

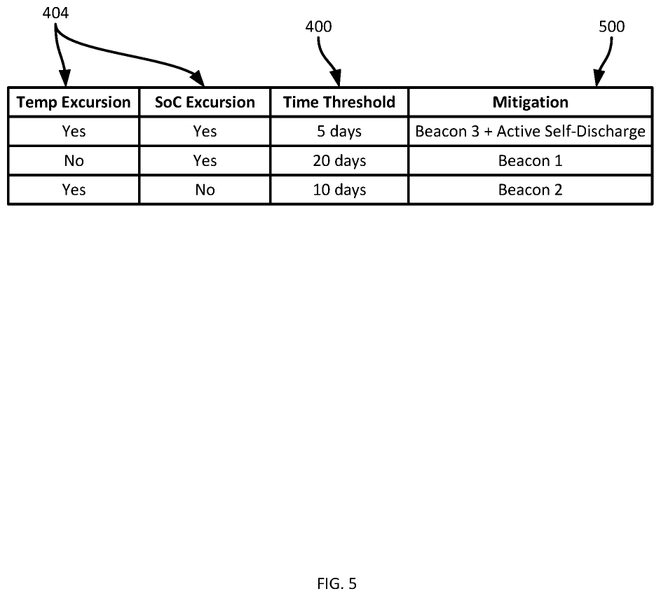

In some examples, as shown in FIG. 5, the thresholds 400 and criteria 404 can be stored in conjunction with mitigation action definitions 500, e.g., such that the controller 208 selects one or more mitigation actions based on which thresholds are exceeded. The example mitigation actions in FIG. 5 include beacons, e.g., emitted via the communications interface 212, containing severity levels from “1” to “3”. When both the temperature and SoC thresholds are exceeded, the controller 208 can also be configured to implement an active self-discharge operation, to reduce the SoC despite being in an idle state.

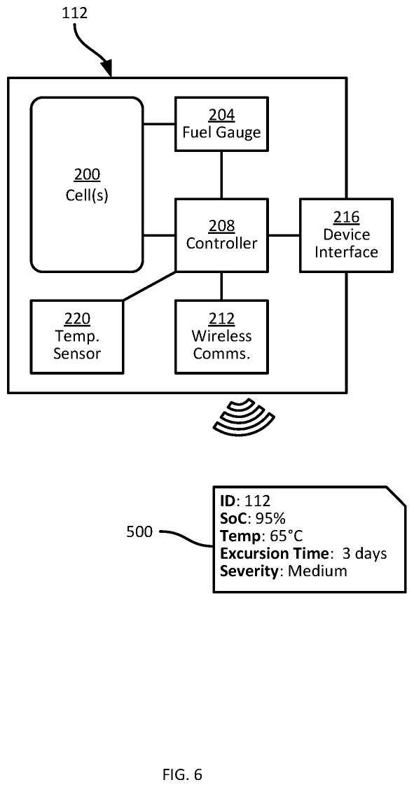

FIG. 6 illustrates an example performance of block 325, for example following selection of the “Beacon 2” action from FIG. 5. The controller 208 is configured to control the interface 212 to broadcast a beacon 500 (e.g., a BLE beacon) containing an identifier of the battery 112, as well as one or more additional information elements. For example, the beacon 500 contains a current SoC, a current ambient temperature, and a current value of the excursion timer. The beacon 500 also contains a severity indicator, e.g., selected from “Low” (for Beacon 1), “Medium” (for Beacon 2), and “High” (for Beacon 3). A wide variety of other severity indicators can also be selected dynamically, e.g., a score based on the magnitude of SoC and/or temperature excursion. The beacon 500 can be broadcast periodically (e.g., every thirty seconds, or at another suitable frequency). Devices, such as the device 100, can be configured to display such beacons to their operators, relay the beacons to a server, or the like.

The active self-discharge action shown in FIG. 5 can include initiating execution of a process at the controller 208 to increase the power draw of the controller 208, such as increasing a frequency of fuel gauge computations (when the controller 208 itself implements the fuel gauge), executing a hash function, or the like. Through active self-discharge, the battery 112 may be able to reduce SoC below the threshold from block 310. In other examples, the battery 112 can include a load switch, e.g., an integrated resistor or the like, and the controller 208 can connect the resistor to the cells 200 to deplete the cells 200 until the SoC threshold is no longer exceeded.

Returning to FIG. 3, at block 330, following block 325 or a negative determination at block 320, the controller 208 is configured to determine whether the excursion(s) detected at block 310 have been resolved. In other words, at block 330 the controller 208 is configured to determine whether the temperature and/or SoC remain above the corresponding thresholds. When the determination at block 330 is negative, the controller 208 is configured to repeat blocks 320 and 325 as described above, e.g., selecting additional mitigation actions and/or adjusting the time threshold based on monitored conditions. As will be apparent, the SoC or temperature may change over time, and thus may rise above their thresholds are fall back below their thresholds. When, for example, SoC remains above the threshold but ambient temperature falls below the temperature threshold, the controller 208 can be configured to adjust the time threshold according to a ratio of the time elapsed. For example, if the temperature and SoC exceeded their respective thresholds for two days (e.g., 40% of the five-day limit shown in FIG. 4), and the temperature then falls below the temperature threshold, the controller 208 can adjust the time threshold from five days (e.g., with three days remaining) to twenty days, with eight days remaining (e.g., 60% remaining).

When the determination at block 330 is affirmative (e.g., when the temperature and SoC are below their respective thresholds for at least a certain number of samples), the controller 208 can be configured to terminate the excursion timer at block 335, ceasing mitigating actions initiated at block 325, and return to block 305.

As noted earlier, in some examples the device 100, rather than the battery 112, can perform certain functions described herein, such as the method 300. The device 100 can, for example, obtain temperature and SoC measurements from the battery 112 for use in the performance of the method 300.

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

Certain expressions may be employed herein to list combinations of elements. Examples of such expressions include: “at least one of A, B, and C”; “one or more of A, B, and C”; “at least one of A, B, or C”; “one or more of A, B, or C”. Unless expressly indicated otherwise, the above expressions encompass any combination of A and/or B and/or C.

It will be appreciated that some embodiments may be comprised of one or more specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Moreover, an embodiment can be implemented as a computer-readable storage medium having computer readable code stored thereon for programming a computer (e.g., comprising a processor) to perform a method as described and claimed herein. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

1. A method, comprising:
monitoring an ambient temperature associated with a battery pack;
in response to detecting that the ambient temperature exceeds a temperature threshold, initializing an excursion timer;
determining whether the excursion timer exceeds a time threshold; and
when the excursion timer exceeds the time threshold, executing a mitigation action at the battery pack.

2. The method of claim 1, further comprising:
prior to initiating monitoring of the ambient temperature, determining that the battery pack is idle.

3. The method of claim 1, wherein executing the mitigation action includes:
controlling a wireless communications interface of the battery pack to transmit a beacon containing an indication that the excursion timer has exceeded the time threshold.

4. The method of claim 3, wherein the beacon further contains an excursion severity indicator based on at least one of (i) a current value of the excursion timer, and (ii) a difference between the ambient temperature and the temperature threshold.

5. The method of claim 1, further comprising, after initializing the excursion timer:
in response to detecting that the ambient temperature has fallen below the temperature threshold, terminating the excursion timer.

6. The method of claim 1, further comprising:
monitoring a state of charge of the battery pack;
in response to detecting that the state of charge exceeds a charge threshold, adjusting the time threshold.

7. The method of claim 1, wherein executing the mitigation action includes:
initiating an active self-discharge operation at the battery pack.

8. A battery pack, comprising:
a temperature sensor; and
a controller configured to:
monitor an ambient temperature associated with the battery pack;
in response to detecting that the ambient temperature exceeds a temperature threshold, initialize an excursion timer;
determine whether the excursion timer exceeds a time threshold; and
when the excursion timer exceeds the time threshold, execute a mitigation action at the battery pack.

9. The battery pack of claim 8, wherein the controller is configured to:
prior to initiating monitoring of the ambient temperature, determine that the battery pack is idle.

10. The battery pack of claim 8, wherein the controller is configured to execute the mitigation action by:
controlling a wireless communications interface of the battery pack to transmit a beacon containing an indication that the excursion timer has exceeded the time threshold.

11. The battery pack of claim 10, wherein the beacon further contains an excursion severity indicator based on at least one of (i) a current value of the excursion timer, and (ii) a difference between the ambient temperature and the temperature threshold.

12. The battery pack of claim 8, wherein the controller is configured to, after initializing the excursion timer:
in response to detecting that the ambient temperature has fallen below the temperature threshold, terminate the excursion timer.

13. The battery pack of claim 8, wherein the controller is configured to:
monitor a state of charge of the battery pack;
in response to detecting that the state of charge exceeds a charge threshold, adjust the time threshold.

14. The battery pack of claim 8, wherein the controller is configured to execute the mitigation action by:
initiating an active self-discharge operation at the battery pack.

15. A device, comprising:
a processor configured to:
monitor an ambient temperature associated with a battery pack;
in response to detecting that the ambient temperature exceeds a temperature threshold, initialize an excursion timer;
determine whether the excursion timer exceeds a time threshold; and
when the excursion timer exceeds the time threshold, initiate a mitigation action at the battery pack.

16. A method, comprising:
monitoring a state of charge level associated with a battery pack;
in response to detecting that the state of charge level exceeds a threshold, initializing an excursion timer;
determining whether the excursion timer exceeds a time threshold; and
when the excursion timer exceeds the time threshold, executing a mitigation action at the battery pack.
